(19) United States
(12) Patent Application Publication
(10) Pub. No.: US 2011/0204322 A1
(43) Pub. Date: Aug. 25, 2011

(54) Optoelectronic Semiconductor Body and Method for Producing an Optoelectronic Semiconductor Body

(75) Inventors: Guido Weiss, Regensburg (DE); Berthold Hahn, Hemau (DE); Ulrich Zehnder, Rettenbach (DE); Andreas Weimar, Regensburg (DE)

(73) Assignee: OSRAM Opto Semiconductors GmbH, Regensburg (DE)

(21) Appl. No.: 12/745,683

(22) PCT Filed: Nov. 26, 2008
(86) PCT No.: PCT/DE08/01957

§ 371 Date: Nov. 8, 2010

(30) Foreign Application Priority Data
Nov. 30, 2007 (DE) 10 2007 057 756.9

(51) Int. Cl. H01L 33/06

(52) U.S. Cl. 257/13; 257/E33.012

(57) ABSTRACT

An optoelectronic semiconductor body is provided which has an epitaxial semiconductor layer sequence based on nitride compound semiconductors. The semiconductor layer sequence comprises a buffer layer, which is nominally undoped or at least partially n-conductively doped, an active zone, which is suitable for emitting or receiving electromagnetic radiation, and a contact layer, which is n-conductively doped, arranged between the buffer layer and the active zone. The n-dopant concentration is greater in the contact layer than in the buffer layer. The semiconductor layer sequence contains a recess, which extends through the buffer layer and in which an electrical contact material is arranged and adjoins the contact layer. A method is additionally indicated which is suitable for producing such a semiconductor body.

This application claims priority from German patent application 10 2007 057 756.9, whose disclosure content is hereby included by reference.

The present application relates to an optoelectronic semiconductor body with an epitaxial semiconductor layer sequence, which is based on a nitride compound semiconductor. The semiconductor layer sequence is provided with an electrical contact material in such way that the latter adjoins an n-conductively doped epitaxial semiconductor layer of the semiconductor layer sequence. The application additionally relates to a method of producing such an optoelectronic semiconductor body.

US 2007/0012944 A1 discloses an optoelectronic semiconductor body of the above-mentioned type. The semiconductor body described comprises for example an n-conductively doped epitaxial layer of GaN, which forms an outer major surface of the semiconductor body remote from a p-conductively doped epitaxial layer. On the major surface of the n-conductively doped epitaxial semiconductor layer there is arranged an electrical contact material in the form of a metallic bond pad. On the opposite side of the epitaxial semiconductor layer sequence from the major surface, a further electrical contact material adjoins a p-conductively doped epitaxial semiconductor layer.

It is an object of the invention to provide an optoelectronic semiconductor body in which particularly reliable electrically conductive contact may be achieved between an electrical contact material and an n-conductively doped epitaxial semiconductor material, which is based on a nitride compound semiconductor, wherein this contact is additionally intended to have the lowest possible electrical resistance. It is additionally intended to provide a method of producing such an optoelectronic semiconductor body.

An optoelectronic semiconductor body is provided which has an epitaxial semiconductor layer sequence based on nitride compound semiconductors. The semiconductor layer sequence comprises an epitaxial buffer layer, an active zone and an epitaxial contact layer arranged between the buffer layer and the active zone. In one embodiment the buffer layer and the contact layer are in particular based on nitride compound semiconductors.

“Based on nitride compound semiconductors” means that the semiconductor layer sequence comprises at least one layer and preferably a plurality of layers comprising a nitride compound semiconductor material or a plurality of nitride compound semiconductor materials. Nitride compound semiconductors are compound semiconductor materials which contain nitrogen, such as materials from the system InₓAl_{y}Ga_{1-x-y}N with 0≦x≦1, 0≦y≦1 and x+y≦1. This material does not absolutely have to exhibit a mathematically exact composition according to the above formula. Instead, it may comprise one or more dopants and additional constituents which do not substantially modify the physical characteristics of the material. For simplicity's sake, however, the above formula includes only the fundamental constituents of the crystal lattice (Al, Ga, In, N), even if these may in part be replaced and/or supplemented by further substances.

In one embodiment the buffer layer comprises GaN. Additionally or as an alternative, the contact layer comprises GaN. This means that both Ga and N are contained in these layers as fundamental constituents of the material. However, the material of the layers is not necessarily a binary semiconductor material, but may instead also be a ternary or a quaternary semiconductor material. A material which comprises GaN may for the purposes of the present application in particular also be AlGaN, InGaN or AlInGaN. In one advantageous embodiment the buffer layer and additionally or alternatively the contact layer comprises a binary semiconductor material with GaN.

In the semiconductor sequence the optoelectronic semiconductor body comprises a recess, which extends out from one side of the semiconductor layer through the buffer layer. According to one embodiment of the semiconductor body the recess ends in a region of the contact layer.

An electrical contact material is arranged in the recess, which material adjoins the contact layer in the recess. This offers the possibility of forming an electrical contact not or not only between the contact material and an outside layer of the epitaxial semiconductor layer sequence, but rather in particular between the electrical contact material and the contact layer which is covered by the buffer layer and is partially exposed by the recess. In this way, the buffer layer may be optimised for example with regard to its crystal quality and the contact layer may be optimised with regard to its contactability by means of an electrical contact material.

The electrical contact material is not a semiconductor material of the epitaxial semiconductor layer sequence. In one embodiment the electrical contact material comprises metallically conductive material. In a further development, the contact material comprises at least one metal and/or at least one transparent electrically conductive oxide (TCO).

In a further embodiment of the semiconductor body the buffer layer has a lower n-dopant concentration than the contact layer. The buffer layer may in particular be nominally undoped or only partially nominally n-conductively doped. In one configuration, the maximum n-dopant concentration within the buffer layer amounts to less than 3×10¹⁸ cm⁻³ or less than 1×10¹⁸ cm⁻³. The maximum n-dopant concentration within the buffer layer may advantageously also amount to less than 7×10¹⁷ cm⁻³ or less than 5×10¹⁷ cm⁻³.

The n-dopant concentration in the contact layer amounts in one embodiment to at least 3×10¹⁸ cm⁻³, 5×10¹² cm⁻³, 7×10¹⁸ cm⁻³ or 1×10¹⁹ cm⁻³. In general, it is advantageous for the n-dopant concentration in the contact layer to be as high as possible.

In a further embodiment the buffer layer has a thickness of greater than or equal to 0.15 μm, preferably of 0.5 μm. The thickness may in particular also be greater than 0.7 μm or greater than 1 μm.

In a further embodiment an outer surface of the buffer layer has an average roughness which is more than twice the average roughness of the bottom surface of the recess. The average roughness of the outer surface is advantageously more than 5 times the average roughness of the bottom surface of the recess.

Additionally or alternatively, an outer surface of the buffer layer has an average roughness which is more than twice the average roughness of a surface of the electrical contact material remote from the semiconductor sequence. The average roughness of the outer surface is advantageously more than 5 times the average roughness of the surface of the electrical contact material remote from the semiconductor sequence.

In a further embodiment the electrical contact material is connected electrically conductively to a bond pad of the semiconductor body or forms a bond pad.

In a further embodiment the recess extends into the contact layer.

In a further embodiment the semiconductor body has no epitaxial substrate.

In a further embodiment a further electrical contact material is arranged on the opposite side of the semiconductor layer sequence from the recess.

A method of producing an optoelectronic semiconductor body is indicated, in which an epitaxial semiconductor layer sequence is provided which is based on nitride compound semiconductors. The semiconductor layer sequence contains an epitaxial buffer layer, an active zone and an epitaxial contact layer. The buffer layer is nominally undoped or at least partially n-conductively doped. The active zone is suitable for emitting or receiving electromagnetic radiation. The contact layer is arranged between the buffer layer and the active zone. In a further method step a recess is formed through the buffer layer and at least as far as the contact layer. Electrical contact material is arranged in the recess, such that it adjoins the contact layer.

In an advantageous embodiment of the method an n-dopant concentration in the contact layer is greater than in the buffer layer.

In a further embodiment the recess is made deep enough to extend into the contact layer.

In a further embodiment an outer surface of the buffer layer is roughened. Roughening of the outer surface of the buffer layer advantageously takes place once the contact material has been arranged in the recess.

Further advantages, preferred embodiments and further developments of the optoelectronic semiconductor body are revealed by the exemplary embodiments explained below in conjunction with the figures, in which:

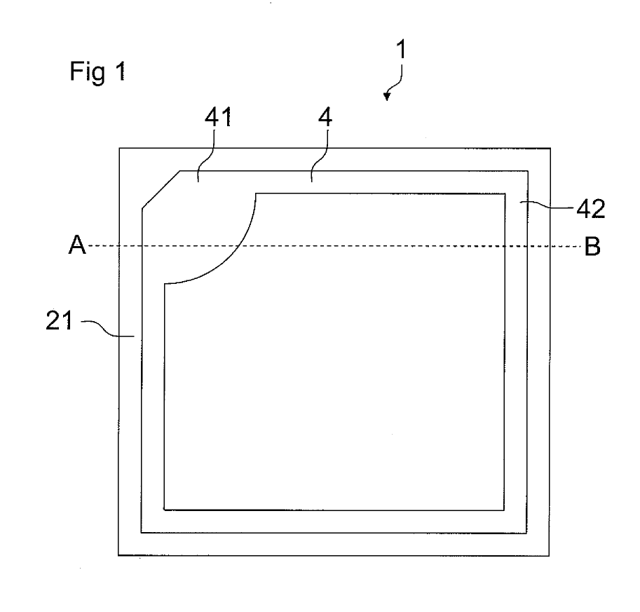

FIG. 1 is a schematic plan view of an exemplary embodiment of the optoelectronic semiconductor body,

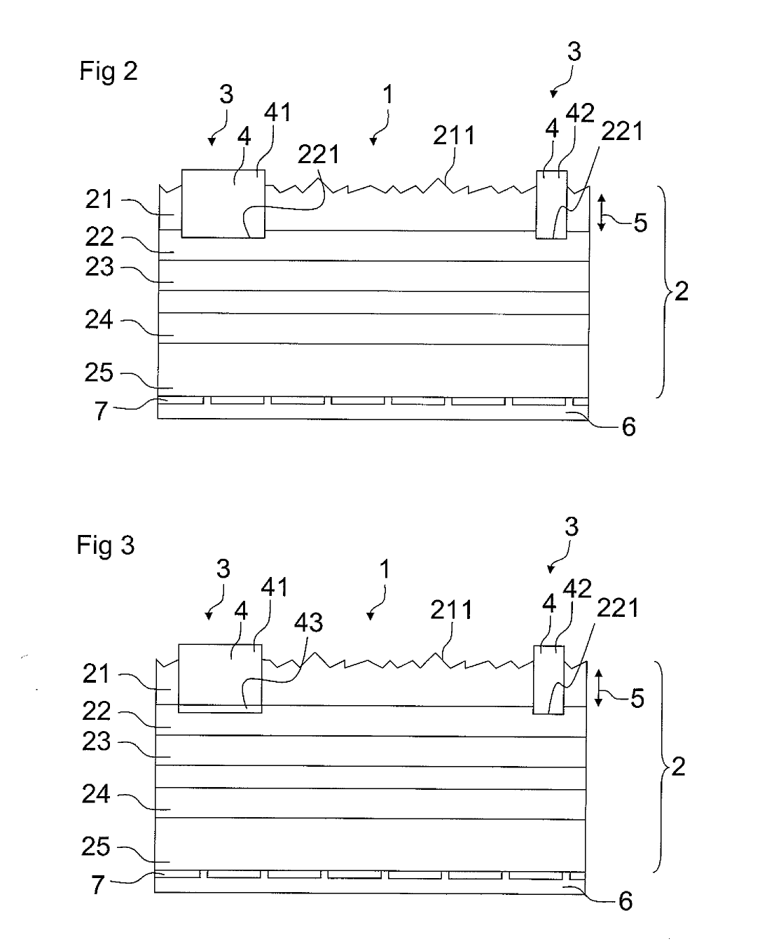

FIG. 2 is a schematic sectional view of the optoelectronic semiconductor body shown in FIG. 1,

FIG. 3 is a schematic sectional view of the optoelectronic semiconductor body according to a second exemplary embodiment,

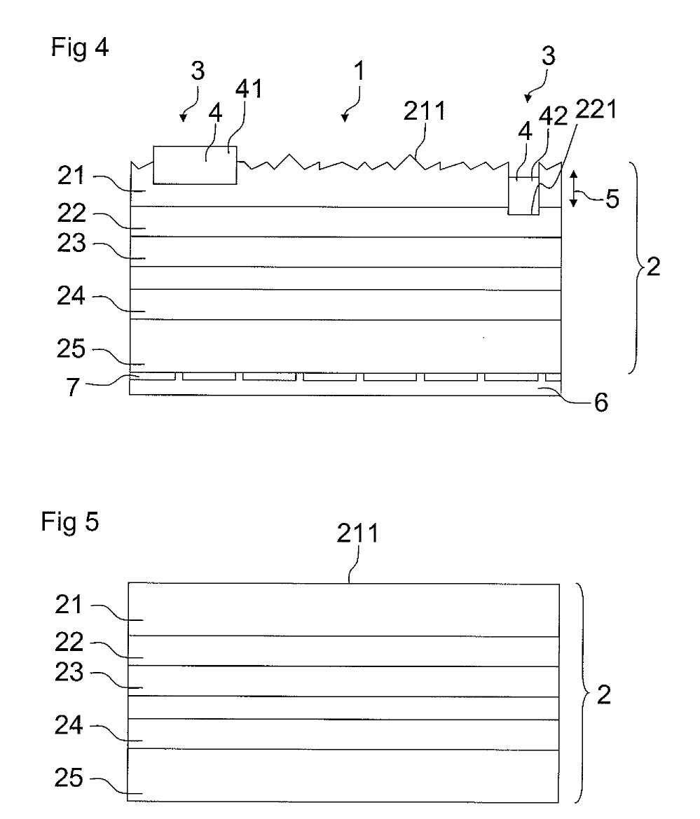

FIG. 4 is a schematic sectional view of the optoelectronic semiconductor body according to a third exemplary embodiment,

FIGS. 5 to 7 are schematic sectional views of an epitaxial semiconductor layer sequence during various stages of the method according to a first exemplary embodiment, and

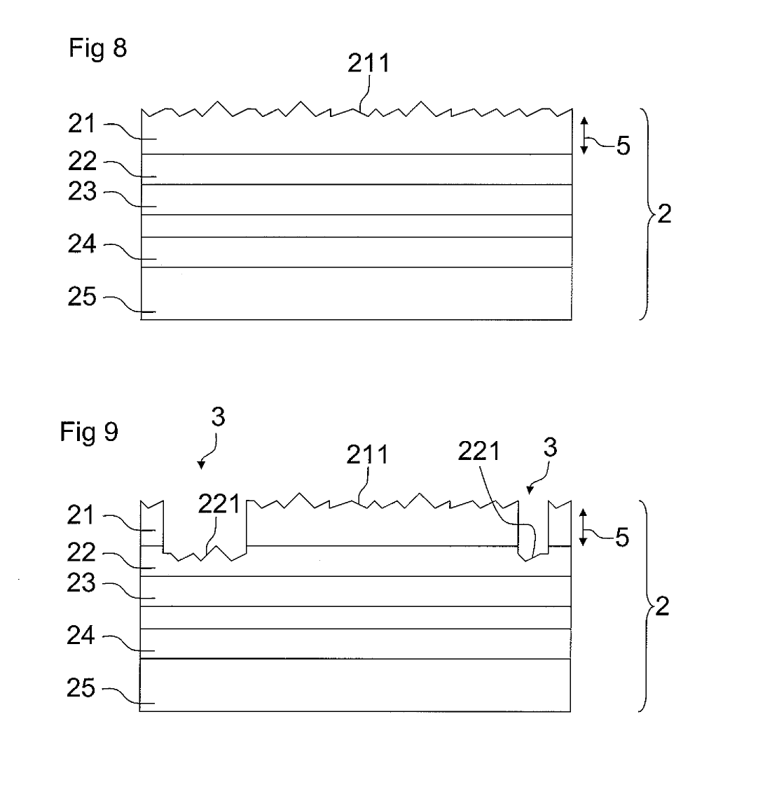

FIGS. 8 and 9 are schematic sectional views of an epitaxial semiconductor layer stack during various stages of the method according to a second exemplary embodiment.

In the exemplary embodiments and figures, identical or identically acting components are in each case provided with the same reference numerals. The components illustrated and the size ratios of the components to one another should not be regarded as to scale. Instead, some of the details in the figures are shown exaggeratedly large for ease of understanding.

In the plan view shown in FIG. 1 of an optoelectronic semiconductor body 1, a buffer layer 21 of an epitaxial semiconductor layer stack and a contact material 4 are visible. In the exemplary embodiment illustrated, the buffer layer 21 is an outer layer of the semiconductor layer stack, i.e. its major surface remote from the semiconductor layer stack bounds the semiconductor layer stack on one of its two major sides. The major surfaces of a layer should in each case be understood to be the two mutually opposing surfaces which bound the layer perpendicularly to its main plane of extension. Accordingly, the major sides of the semiconductor layer stack are those two sides which are bounded by major surfaces of layers of the semiconductor layer stack.

The buffer layer does not necessarily have to be the outer layer, however. Instead, it may for example be covered at least in part by a further epitaxial semiconductor layer of the layer stack, which for example forms the majority of the outer surface on this major side of the semiconductor layer stack.

The electrical contact material 4 takes the form of a frame. In FIG. 1 the frame is continuous, it could however also be interrupted. It is likewise possible in principle for the electrical contact material 4 to be applied in any other desired form to the semiconductor stack.

Part of the electrical contact material 4 forms a bond pad 41 or is connected electrically conductively to the bond pad 41. The bond pad 41 has an outer surface which is suitable for fastening a bonding wire mechanically and electrically conductively thereto with the material which forms the outer surface of the bond pad.

Electrical contact tracks 42 extend from the bond pad 41. The purpose of these is for electrical current to be injected into the semiconductor layer sequence as evenly as possible over the entire semiconductor layer sequence during operation of the optoelectronic semiconductor body. The contact tracks 42 extend for example along the side edge of the semiconductor layer sequence. However, it is for example also possible for at least one contact track to extend through the middle of the semiconductor layer sequence.

FIGS. 2 to 9 each show schematic sectional views of the optoelectronic semiconductor body or the epitaxial semiconductor layer sequence according to different exemplary embodiments, these sectional views corresponding approximately to a plan view of a section along the broken line AB shown in FIG. 1.

In the exemplary embodiment illustrated in FIG. 2 the electrical contact material 4 is arranged in at least one recess 3. The recess 3 extends from an outer major surface of the semiconductor layer sequence 2 through the buffer layer 21 and at least as far as the contact layer 22. In the example illustrated, the buffer layer directly adjoins the contact layer 23. However it is in principle also possible for at least one further semiconductor layer also to be arranged between the buffer layer and the contact layer.

The recess 3 extends for example into the contact layer 22. Relative to the total thickness of the contact layer 22, the recess may extend into the contact layer 22 for example by 20% to 80% inclusive of the thickness. The recess 3 ends for example roughly halfway into the thickness of the contact layer 22. Thickness is measured perpendicularly to a main plane of extension of the contact layer.

An electrical contact material 4 is arranged in the recess 3, which material adjoins the contact layer 22 inside the recess. The contact material 4 in particular adjoins a bottom surface 221 of the recess 3, which is formed at least in part by material of the contact layer 22. At the boundary surface between the bottom surface 221 and the electrical contact material 4 an electrically readily conductive contact is formed between the contact material 4 and the contact layer 22. The electrical contact has approximately the characteristics of an ohmic contact. In specialist circles it is therefore often simply known as ohmic contact.

The electrical contact material 4 projects in part out of the recess 3, i.e. some of the electrical contact material 4 projects away from the epitaxial semiconductor layer stack 2. This makes the electrical contact material 4, in particular in the region of the bond pad 41, readily electrically contactable from outside.

The depth of the recess 3 is at least as great as the thickness 5 of the buffer layer 21. Preferably, the depth of the recess 3 is greater than the thickness 5 of the buffer layer 21. The thickness 5 of the buffer layer 21 amounts for example to more than 0.15 μm. It also amounts for example to less than 5 p.m. Highly suitable thicknesses 5 are for example 0.5 μm, 1 μm, 1.5 μm or 2 μm.

The semiconductor body is in particular a radiation-emitting and/or radiation-detecting semiconductor chip based on nitride compound semiconductors. These include in this case in particular those semiconductor chips in which the epitaxially produced semiconductor layer sequence contains at least one individual layer which comprises a material from the nitride compound semiconductor material system.

The active zone comprises a pn-junction, a double heterostructure, a single quantum well (SQW) or a multi quantum well (MQW) for radiation generation. The term quantum well structure does not here have any meaning with regard to the dimensionality of the quantisation. It thus encompasses inter alia quantum troughs, quantum wires and quantum dots and any combination of these structures. Examples of MQW structures are described in the documents WO 01/39282, U.S. Pat. No. 5,831,277, U.S. Pat. No. 6,172,382 B1 and U.S. Pat. No. 5,684,309, whose disclosure content is hereby included in this respect by reference.

For example, the buffer layer 21 and the contact layer 22 are in each case a GaN layer.

The outer surface 211 of the buffer layer 21 is roughened. It comprises unevennesses which are suitable for reducing total reflections at the outer surface 211 and for increasing radiation outcoupling via the outer surface 211 and out of the semiconductor layer stack 2. The outer surface 211 is in particular microstructured. A semiconductor chip with a microstructured outcoupling surface and a method of microstructuring a radiation outcoupling surface of a radiation-emitting semiconductor layer sequence based on nitride compound semiconductor material are disclosed for example in WO 2005/106972, whose disclosure content is hereby included in this respect in the present application.

Unlike the outer surface 211 of the buffer layer 21, the bottom surface 221 of the recess 3 is as far as possible planar. It displays a roughness which is for example more than 5 times less than the roughness of the outer surface 211. It has been established that a bottom surface 221 which is as smooth as possible is advantageous in forming an electrically conductive contact between the contact material 4 and the contact layer 22.

The contact material 4 comprises for example a metal or a plurality of metals or consists of one or more metals. In addition or as an alternative, the electrical contact material 4 may however also comprise a transparent electrically conductive oxide or “TCO”, such as for example indium tin oxide (ITO).

In one exemplary embodiment the contact material 4 comprises a layer with titanium, which adjoins the bottom surface 221, a layer with platinum applied to the layer with titanium and a layer with gold applied to the layer with platinum. The layer with titanium displays for example a thickness of between 50 and 200 nm inclusive, for example 100 nm. The layer with platinum displays for example a thickness of between 50 and 300 nm inclusive, for example 100 nm. The layer with gold displays for example a thickness of between 0.5 and 4 μm inclusive. The layers, in particular the layer with gold, may also be thicker still. The layers may in each case also consist of the stated material.

The buffer layer 21 is for example a nominally undoped GaN layer. Nominally undoped means that it has a markedly lower n-dopant concentration than nominally n-conductively doped semiconductor layers of the epitaxial semiconductor layer stack 2. For example, the dopant concentration in the entire buffer layer is less than 1×10¹⁸ cm⁻³, preferably less than 7×10¹⁷ cm⁻³, particularly preferably less than 5×10¹⁷ cm⁻³. The dopant concentration may amount, for example, to at most roughly 3×10¹⁷ cm⁻³.

Alternatively, the buffer layer 21 may also be at least partially n-conductively doped. The dopant concentration in the buffer layer 21 is however less than the dopant concentration in the contact layer 22. For example, the dopant concentration in the buffer layer 21 amounts overall to less than 3×10¹⁸ cm⁻³. Compared with the buffer layer, the contact layer 22 comprises a relatively large dopant concentration. The contact layer is for example n-conductively doped, with a dopant concentration of for example greater than or equal to 8×10¹⁸ cm⁻³. For example, the n-dopant concentration in the contact layer amounts to approximately 1×10¹⁹ cm⁻³ or more. It is also possible for just part of the contact layer 22 to comprise such a high dopant concentration, and for the dopant concentration in other parts of the contact layer 22 to be somewhat lower.

It has been established that the epitaxial semiconductor layer sequence 2 may advantageously be produced, both with regard to its crystal quality and with regard to its electrical contactability, if the dopant concentration in the buffer layer 21 is as low as possible and the dopant concentration in the contact layer 22 is as high as possible in comparison thereto. A buffer layer 21 which is as thick as possible and has as low a dopant concentration as possible may have a positive effect on the crystal quality of the semiconductor layer sequence.

The semiconductor body 1 shown in FIG. 2 for example has no epitaxial substrate. The semiconductor layer sequence 2 was grown on an epitaxial substrate, for example, beginning with the buffer layer 21. The epitaxial substrate was then removed. In the process, all the material of the epitaxial substrate may be removed completely. Alternatively, it is however also possible for some of the material of the epitaxial substrate to remain as part of the semiconductor body and not be removed.

In general the optoelectronic semiconductor body is in particular a thin-film luminescent diode chip.

A thin-film luminescent diode chip is distinguished in particular by at least one of the following characteristic features:
a reflective layer is applied to or formed on a first major surface, facing a support element, of the radiation-generating, epitaxial semiconductor layer sequence, said reflective layer reflecting at least some of the electromagnetic radiation generated in the epitaxial semiconductor layer sequence back into it;
the thin-film semiconductor chip includes a support element, which is not the growth substrate on which the semiconductor layer sequence was grown epitaxially but rather is a separate support element, which was attached subsequently to the epitaxial semiconductor layer sequence,
the growth substrate of the epitaxial semiconductor layer sequence is removed from the epitaxial semiconductor layer sequence or thinned in such a way that it is not self-supporting together with the epitaxial semiconductor layer sequence alone, or
the epitaxial semiconductor layer sequence has a thickness in the range of 20 μm or less, in particular in the range of 10 μm.

The support element is preferably permeable to radiation emitted by the semiconductor chip.

In addition, the epitaxial semiconductor layer sequence preferably contains at least one semiconductor layer with at least one surface which comprises an intermixing structure, which ideally leads to an approximately ergodic distribution of the light in the epitaxial semiconductor layer sequence, i.e. it exhibits scattering behaviour which is as ergodically stochastic as possible.

The basic principle of a thin-film semiconductor chip is described for example in I. Schnitzer et al., Appl. Phys. Lett. 63 (16), 18 Oct. 1993, 2174-2176, whose disclosure content is hereby included in this respect by reference. Examples of thin-film semiconductor chips are described in the documents EP 0905797 A2 and WO 02/13281 A1, whose disclosure content is hereby included in this respect by reference.

The semiconductor body does not however have to be a luminescent diode chip, but rather may also be a radiation-detecting chip, for example for an optical sensor.

In the case of the semiconductor body shown in FIG. 2, a further electrical contact material 6, for example, is arranged on the opposite side of the semiconductor sequence 2 from the recess 3, which further electrical contact material forms a contact electrode for the semiconductor body 1. The contact material 4 in the recess 3 forms an n-electrode or part of such an n-electrode. The contact material 6 of the oppositely located electrode is applied to an electrically insulating layer 7.

The electrically insulating layer 7 comprises for example a dielectric material such as for example silicon dioxide or consists of such a material. In addition, the layer 7 contains at least one recess, which extends vertically through the layer 7. In the region of the recess the semiconductor layer stack 2 is electrically conductively contactable. The electrically insulating layer 7 preferably comprises a plurality of such recesses. Such a combination of electrically insulating material 7 and electrical contact material 6 may display high reflectivity.

In addition to the buffer layer 21 and the contact layer 22, the semiconductor layer sequence 2 comprises for example an active zone 24 and a p-conductively doped semiconductor layer 25. It is possible for example for an n-conductively doped semiconductor layer optionally to be arranged between the p-conductively doped semiconductor layer 25 and the electrical contact material 6, but this is not shown in FIG. 2. In this case, a tunnel contact may be provided between the p-conductively doped semiconductor layer 25 and said n-conductively doped semiconductor layer.

It is furthermore possible for one or more further semiconductor layers to be arranged between the contact layer 22 and the active zone 24. An n-conductively doped semiconductor layer 23 is for example arranged at this location, which adjoins the contact layer 22 and is n-conductively doped with a dopant concentration of approximately 3.5×10⁸ cm⁻³. Silicon is suitable as the n-dopant, for example.

Unlike in the exemplary embodiment described in conjunction with FIG. 2, in the case of the semiconductor body 1 illustrated in FIG. 3 at least part of the electrical contact material 4 in the recess 3 is underlaid with an electrically insulating material 43. For example, the bond pad 41 is partially or completely underlaid with the insulating material 43. A dielectric, for example silicon dioxide, is suitable as the insulating material. The insulating material is applied to the bottom surface 221 of the recess, in particular adjoining the bottom surface. By way of the electrically insulating material 43 it is possible to prevent an excessively high local electrical current density from arising under the bond pad 41 during operation of the semiconductor body, which could have a negative effect on the functionality of the optoelectronic semiconductor body.

In the exemplary embodiment illustrated in FIG. 4, the recess 3 has regions of different depths. For example, parts of the recess 3 in which the electrical contact track 42 is arranged are deeper than parts of the recess in which the bond pad 41 is arranged. In principle, it is also possible for the bond pad 41 to be arranged partially or wholly outside the recess 3, i.e. the bond pad is arranged at least partially on the outer surface 211.

In the region of the contact tracks 42 the contact material 4 is arranged wholly inside the recess 3, i.e. the contact material does not project out of the recess 3. On the other hand, in the region of the bond pad 41 the contact material 4 projects at least in part away from the semiconductor layer stack 2, which is favourable with regard to the external electrical contactability of the semiconductor body 1. It is in principle also possible, however, for the electrical contact material 4 which forms the bond pad 41 also to be arranged at least in part or altogether wholly in the recess 3 and not to project beyond the recess 3 or to extend as far as the edge of the recess.

FIGS. 5 to 7 show an exemplary embodiment of the method. In the method a semiconductor layer sequence 2 is provided, which comprises a buffer layer 21, a contact layer 22, an n-conductively doped layer 23, an active zone 24 and a p-conductively doped layer 25. The semiconductor layer sequence may contain still further layers, for example between the n-conductively doped layer 23 and the active zone 24.

On one of its two major sides the semiconductor layer sequence comprises an outer surface 211. This outer surface is formed for example by one of the two major surfaces of the buffer layer 21.

The epitaxial semiconductor layer sequence 2 may be produced by growing the layers on a suitable epitaxial substrate. The epitaxial substrate comprises for example silicon carbide or sapphire. The semiconductor layer sequence 2 is grown here on the epitaxial substrate, for example beginning with the buffer layer 21. Then the epitaxial substrate is for example removed from the semiconductor layer sequence.

Prior to removal of the epitaxial substrate the contact structure shown in each case in FIGS. 2 to 4 may preferably be formed with an electrically insulating layer 7 and an electrical contact material 6, this not being shown in FIGS. 5 to 7 however. Formation of this contact structure may however in principle also proceed after removal of the epitaxial substrate.

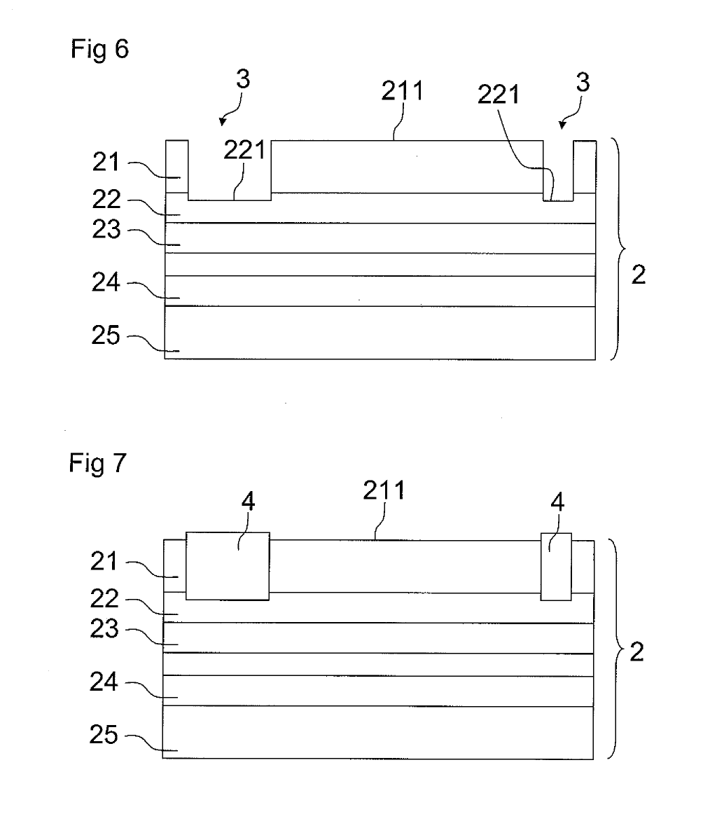

At least one recess 3 is then formed in the semiconductor layer sequence 2. The recess may for example be formed photolithographically, using a photostructurable mask layer. Such a mask layer is not shown in FIGS. 6 and 7, although it may, in a convenient embodiment, also be present during application of the electrical contact material 4, see FIG. 7. Undesired electrical contact material may then advantageously be removed together with the photostructurable mask layer using a lift-off process. Such method steps are in principle known to a person skilled in the art.

Formation of the recess may proceed for example using reactive ion etching and/or for example wet chemically. Conventional method steps such as for example vapour deposition and/or sputtering may also be used to apply the electrical contact material 4.

In the exemplary embodiment of the method a method step for roughening the outer surface 211 is performed only after arrangement of the electrical contact material in the recess 3. In this way, it may be simply ensured that the bottom surface of the recess 221 is as flat or smooth as possible and can no longer be impaired in this respect by a roughening method step. A method of roughening the outer surface 211 is disclosed for example in WO 2005/106972, the disclosure content of which has already been included above in this application by reference. The semiconductor body 1 resulting from the method is illustrated in FIG. 2.

An alternative example of the method is shown in FIGS. 8 and 9. One difference is that a method step for roughening the outer surface 211 takes place prior to formation of the recess 3. The recess 3 is produced for example by etching into a rough surface, which results in the bottom surface 211 of the recess 3 likewise being rough. The roughness of the bottom surface 221 may here be somewhat less pronounced than the roughness of the outer surface 211. For example the roughness of the bottom surface 221 is however less than 5 times or less than 2 times less than the roughness of the outer surface 211. It has been established that even with a rough bottom surface 221 a good electrically conductive contact may be formed between the electrical contact material 4 and the contact layer 22. Although it appears advantageous for the bottom surface of the recesses to be as smooth as possible, the bottom surface 221 may however also be rough.

The optoelectronic semiconductor body and the method are not limited to the exemplary embodiments by describing them with reference to such. Rather, the application encompasses any novel feature and any combination of features, including in particular any combination of features in the claims, even if this feature or this combination is not itself explicitly indicated in the claims or exemplary embodiments.

1. An optoelectronic semiconductor body with an epitaxial semiconductor layer sequence, which is based on nitride compound semiconductors and which contains an epitaxial buffer layer, an active zone and an epitaxial contact layer, wherein:
the buffer layer is nominally undoped or at least partially n-conductively doped,
the active zone is suitable for emitting or receiving electromagnetic radiation,
the contact layer is arranged between the buffer layer and the active zone and is n-conductively doped,
the n-dopant concentration in the contact layer is greater than in the buffer layer, and
the semiconductor layer sequence contains a recess, which extends through the buffer layer and in which an electrical contact material is arranged and adjoins the contact layer.

2. The optoelectronic semiconductor body according to claim 1, wherein the buffer layer has a thickness of greater than or equal to 0.15 μm.

3. The optoelectronic semiconductor body according to claim 1, wherein the buffer layer has a thickness of greater than or equal to 0.5 μm.

4. The optoelectronic semiconductor body according to claim 1, wherein an outer surface of the buffer layer has an average roughness which is more than twice the average roughness of the bottom surface of the recess.

5. The optoelectronic semiconductor body according to claim 1, wherein the average roughness of the outer surface of the buffer layer is at least 5 times the average roughness of the bottom surface of the recess.

6. The optoelectronic semiconductor body according to claim 1, wherein the electrical contact material is connected electrically conductively to a bond pad of the semiconductor body or forms a bond pad.

7. The optoelectronic semiconductor body according to claim 1, wherein the contact layer has a dopant concentration of greater than or equal to 3×10¹⁸ cm⁻³.

8. The optoelectronic semiconductor body according to claim 1, wherein the contact layer has a dopant concentration of greater than or equal to 7×10¹⁸ cm⁻³.

9. The optoelectronic semiconductor body according to claim 1, wherein the recess extends into the contact layer.

10. The optoelectronic semiconductor body according to claim 1, wherein the semiconductor body has no epitaxial substrate.

11. The optoelectronic semiconductor body according to claim 1, wherein a further electrical contact material is arranged on the opposite side of the semiconductor layer sequence from the recess.

12. The optoelectronic semiconductor body according to claim 1, wherein the average roughness of the outer surface of the buffer layer is at least 5 times the average roughness of a surface of the electrical contact material remote from the semiconductor layer sequence.

13. The optoelectronic semiconductor body according to claim 1, wherein, in the recess, part of the electrical contact material is underlaid with an electrically insulating material and the electrically insulating material is arranged between the electrical contact material and the contact layer.

14. The optoelectronic semiconductor body according to claim 1,
wherein the electrical contact material forms a bond pad and an electrical contact track;
wherein the recess has regions of different depth; and
wherein parts of the recess in which the electrical contact track is arranged are deeper than parts of the recess in which the bond pad is arranged.

15. The optoelectronic semiconductor body according to claim 1, wherein the electrical contact material forms a bond pad and an electrical contact track, which both adjoin the contact layer.
